(19) United States
(12) Patent Application Publication
(10) Pub. No.: US 2019/0214260 A1
(43) Pub. Date: Jul. 11, 2019

(54) BONDING OF DIAMOND WAFERS TO CARRIER SUBSTRATES

(71) Applicant: ELEMENT SIX TECHNOLOGIES LIMITED, DIDCOT, OXFORDSHIRE (GB)

(72) Inventor: DANIEL FRANCIS, SANTA CLARA, CA (US)

(73) Assignee: ELEMENT SIX TECHNOLOGIES LIMITED, DIDCOT, OXFORDSHIRE (GB)

(21) Appl. No.: 16/306,217

(22) PCT Filed: Jun. 2, 2017
(86) PCT No.: PCT/EP2017/063436

§ 371 Date: Nov. 30, 2018

Related U.S. Application Data
(60) Provisional application No. 62/345,376, filed on Jun. 3, 2016.

(30) Foreign Application Priority Data
Jun. 22, 2016 (GB) 1610886.2

(51) Int. Cl. H01L 21/18; H01L 21/20; H01L 21/683; G03F 7/20

(52) U.S. Cl. CPC H01L 21/187; G03F 7/707; H01L 21/6833; H01L 21/2007

(57) ABSTRACT

A method of bonding a diamond wafer to a carrier substrate. The diamond wafer is placed on the carrier substrate, the diamond wafer having a diameter of at least 50 mm. A voltage is applied to the carrier substrate which induces an electrostatic force which bonds the diamond wafer to the carrier substrate. The voltage applied to the carrier substrate is removed, leaving the diamond wafer bonded to the carrier substrate via residual electrostatic force. A mounted diamond wafer comprises a diamond wafer having a diameter of at least 50 mm and a carrier substrate, wherein the diamond wafer is bonded to the carrier substrate via a residual electrostatic force.

### FIELD OF INVENTION

The present invention relates to the bonding of diamond wafers to carrier substrates for subsequent wafer processing and/or device applications.

### BACKGROUND

It is known that for certain processes and applications it is required to mount a diamond wafer to a carrier substrate. This may be required to increase the mechanical robustness of the diamond wafer, particularly when the diamond wafer is thin. Mounting is also often required to flatten a diamond wafer for subsequent processing steps or device applications. For example, a plain, as-grown, free-standing polycrystalline CVD diamond wafer is bowed due to internal stresses generated during growth. In order to lap and/or polish the diamond wafer it is advantageous to mount the bowed diamond wafer to a carrier wafer to flatten the wafer prior to polishing. A flattened wafer may also be required for applications such as semiconductor applications (e.g. heat spreaders), photolithographic processing, and optical applications (e.g. mirrors).

Mounting of diamond wafers in a flat configuration is also required for semiconductor-on-diamond wafers (e.g. gallium nitride (GaN) on diamond wafers) for subsequent semiconductor device fabrication. In this regard, one approach known in the art is to start with a GaN-on-silicon wafer (or alternatively a GaN-on-silicon carbide wafer), attach a carrier substrate, remove the native silicon substrate and advantageous native strain matching layers, deposit a nucleation layer, grow polycrystalline CVD diamond over the nucleation layer, and then remove the carrier substrate to form a composite GaN-on-diamond wafer for semiconductor device manufacture. Such processes are described, for example, in WO2006/113539 and WO2014/066740.

One problem is that internal stresses generated during the diamond growth process result in a GaN-on-diamond wafer which is bowed and not suitable for standard semiconductor device fabrication processes which require a highly flat wafer specification. Depending on the thickness of the diamond layer the GaN-on-diamond wafer may also be too thin for standard semiconductor device fabrication processes. Accordingly, it is required to mount the GaN-on-diamond wafer to a carrier substrate. However, this is not straight forward as the mounted GaN-on-diamond wafer must remain flat and also retain chemical and mechanical robustness when exposed to various semiconductor device fabrication processes. One possible solution is to bond the diamond side of a GaN-on-diamond wafer to a low thermal expansion coefficient carrier substrate which may itself be formed of a diamond material such as a free standing polycrystalline CVD diamond wafer which has been lapped and polished to a high flatness specification. The adhesive must also be carefully selected to ensure that the flatness specification and the mechanical and chemical robustness of the wafer is retained both after bonding to the carrier substrate and during the various semiconductor device fabrication processes. Such an approach is described in WO2014/006562. However, such an approach adds significant expense associated with the use of a high cost diamond carrier substrate and with the time required to bond and de-bond the carrier substrate.

More recently, an alternative approach has been developed using a non-diamond carrier substrate bonded to the diamond side of a GaN-on-diamond wafer using an adhesive. According to one aspect of this alternative approach the carrier substrate comprises a layer having a higher coefficient of thermal expansion (CTE) than diamond (e.g. silicon) in addition to a layer having a lower coefficient of thermal expansion (CTE) than diamond (e.g. quartz). The thermal expansion coefficient of the layers and layer thicknesses of the carrier substrate can be tuned such that internal residual stresses ensure near zero bow of the semiconductor-on-diamond-on-carrier substrate wafer. Such a mounted semiconductor-on-diamond is therefore suitable for device manufacture on a standard fabrication line. After device fabrication the carrier substrate may be released and reused.

This alternative approach has the advantage of using a lower cost, non-diamond carrier substrate while still managing thermal expansion mismatches both during the bonding process and during the various semiconductor device fabrication processes. However, the adhesion process to achieve the required flatness specification can still be difficult and the adhesive itself may be a source of weakness in subsequent chemical processing steps during semiconductor device fabrication.

### SUMMARY OF INVENTION

In light of the above, alternative bonding solutions have been explored. In this regard, the present inventors have assessed the possibility of utilizing an electrostatic bonding technique for bonding a diamond wafer to a carrier substrate.

Electrostatic clamping is a known technique for handling semiconductor wafers in semiconductor device fabrication processes. The basic technique involves placing a semiconductor wafer on an electrostatic chuck, applying a voltage to the electrostatic chuck inducing electrostatic forces between the chuck and the semiconductor wafer which clamp the semiconductor wafer to the chuck, subjecting the wafer to device fabrication processes, and then releasing the semiconductor wafer from the chuck. A number of prior art documents disclosing such techniques are briefly discussed below.

U.S. Pat. No. 5,426,558 discloses an electrostatic chuck for releasably holding a semiconductor wafer such as a silicon wafer. The electrostatic chuck is configured such that when a semiconductor wafer is placed on the chuck and a voltage is applied to the chuck, electrostatic forces hold the semiconductor wafer on the chuck. On removal of the electrostatic forces the semiconductor wafer is released and can be removed from the chuck. The chuck comprises a dielectric substrate and electrodes for applying a voltage. The dielectric substrate is made of a material not having polar molecules such that no residual electrostatic force remains after removal of the voltage and the semiconductor wafer can thus be readily removed from the chuck after the voltage is removed. Suitable materials for the dielectric substrate are disclosed including polycrystalline diamond grown by chemical vapour deposition (CVD). In this arrangement the polycrystalline CVD diamond material is an integral part of the electrostatic chuck and is provided in a configuration which is intended to ensure that the diamond material is not electrostatically bonded to the semiconductor wafer after removal of an applied voltage.

U.S. Pat. No. 5,560,780 discloses a similar electrostatic chuck configuration as that described in U.S. Pat. No. 5,426,558 comprising a dielectric layer. The configuration differs in that a polymeric dielectric material (e.g. a polyimide) is utilized and a thin protective layer (e.g. aluminium oxide or aluminium nitride) is provided over the polymeric dielectric material. A semiconductor wafer can then be electrostatically clamped to the chuck and subjected to wafer processing steps. The protective layer prevents damage of the polymeric dielectric material in the electrostatic chuck during these wafer processing steps.

U.S. Pat. No. 5,166,856 also discloses a similar electrostatic chuck configuration as that described in U.S. Pat. No. 5,426,558 comprising a dielectric layer. In the described configuration the dielectric material is formed of a polycrystalline CVD diamond material which is coated over a refractory metal substrate. As with U.S. Pat. No. 5,426,558, the polycrystalline CVD diamond material is an integral part of the electrostatic chuck and is provided in a configuration which is intended to ensure that the diamond material is not electrostatically bonded to the semiconductor wafer after removal of an applied voltage.

D. R. Wright et al., Journal of Vacuum Science & Technology B 13, 1910, 1995 discusses various manufacturing issues of electrostatic chucks including issues of clamping force, clamping and declamping time, and wafer temperature control.

S. Kanno et al., Journal of Vacuum Science & Technology B 21, 2371, 2003 discusses the generation mechanism of residual clamping force in a bipolar electrostatic chuck.

S. Kanno et al., Journal of Vacuum Science & Technology B 23, 113, 2005 discloses a high-temperature electrostatic chuck for use in etching of non-volatile materials.

S. Kanno et al., Journal of Vacuum Science & Technology B 24, 216, 2006 discloses models for predicting clamping pressure between a wafer and an electrostatic chuck.

M. R. Sogard et al., Journal of Vacuum Science & Technology B 25, 2155, 2007 discloses an analysis of Coulomb and Johnsen-Rahbek electrostatic chuck performance for extreme ultraviolet lithography.

A. Mikkelson et al., Journal of Vacuum Science & Technology B 22, 3043, 2004 discloses effects associated with variations in wafer thickness on electrostatic chucking.

M. Nakasuji et al., Journal of Vacuum Science & Technology A 10, 3573, 1992 discloses a low voltage and high speed operating electrostatic wafer chuck.

M. Nakasuji et al., Journal of Vacuum Science & Technology A 12, 2834, 1994 discloses a low voltage and high speed operating electrostatic wafer chuck using sputtered tantalum oxide membrane.

All of the methods disclosed in the aforementioned prior art documents involve placing a semiconductor wafer on an electrostatic chuck, applying a voltage to the electrostatic chuck inducing electrostatic forces between the chuck and the semiconductor wafer which clamp the semiconductor wafer to the chuck, subjecting the wafer to device fabrication processes, and then releasing the semiconductor wafer from the chuck. The aim of the present invention is somewhat different to the approaches described in these prior art citations in that the inventors have been concerned with mounting a diamond wafer to a carrier substrate for subsequent processing rather than mounting a diamond wafer to an electrostatic chuck. Furthermore, electrostatic bonding is usually not possible for electrically insulating substrates. For example, it is not possible to electrostatically bond sapphire wafers in this manner. While the use of diamond in electrostatic clamping techniques is described in the aforementioned prior art, the diamond material is incorporated into the electrostatic chuck and is provided in a configuration which is intended to ensure that the diamond material is not electrostatically bonded to the semiconductor wafer after removal of an applied voltage. That is, the prior art suggests that diamond does not retain a residual electrostatic charge which would enable is to be bonded to a carrier wafer via a residual electrostatic force after removal of the diamond and carrier wafer from the electrostatic chuck.

Despite this apparent indication that such an approach would not be possible for a diamond wafer it has nevertheless been investigated to determine whether such an approach could be made to work for diamond wafers. Surprisingly, the present inventors have found that it is in fact possible to bond a diamond wafer to a carrier substrate using residual electrostatic forces. A true dielectric should not and will not attach to a carrier substrate via a residual electrostatic force. However, it has been found that due to surface conduction on a diamond wafer resulting from diamond surface termination groups or by using an electrically conductive coating on the diamond, it has been found to be possible to electrostatically mount a diamond wafer to a carrier substrate via residual electrostatic forces. Furthermore, for semiconductor-on-diamond wafers such as GaN-on-diamond, the presence of the semiconductor on the diamond wafer can also act as an enabler for electrostatic bonding of the semiconductor-on-diamond wafers to a carrier substrate.

In light of the above, according to one aspect of the present invention there is provided a method of bonding a diamond wafer to a carrier substrate, the method comprising:
placing a diamond wafer on a carrier substrate, the diamond wafer having a diameter of at least 50 mm;
applying a voltage to the carrier substrate which induces an electrostatic force which bonds the diamond wafer to the carrier substrate; and
removing the voltage applied to the carrier substrate leaving the diamond wafer bonded to the carrier substrate via residual electrostatic force.

According to another aspect of the present invention there is provided a mounted diamond wafer comprising:
a diamond wafer having a diameter of at least 50 mm; and
a carrier substrate,
wherein the diamond wafer is bonded to the carrier substrate via a residual electrostatic force.

### BRIEF DESCRIPTION OF THE DRAWINGS

For a better understanding of the present invention and to show how the same may be carried into effect, embodiments of the present invention will now be described by way of example only with reference to the accompanying drawings, in which:

FIG. 1 shows a schematic diagram of the steps involved in bonding a plain free-standing diamond wafer to a carrier substrate;

FIG. 2 shows a schematic diagram of the steps involved in bonding a diamond wafer to a carrier substrate where the diamond wafer comprises an electrically conductive layer provided on a side of the diamond wafer which is bonded to the carrier wafer; and

FIG. 3 shows a schematic diagram of the basic steps involved in bonding a semiconductor-on-diamond wafer to a carrier substrate.

### DETAILED DESCRIPTION

As described in the summary of invention section, the present invention is based on the surprising finding that it is possible to bond a diamond wafer to a carrier substrate using electrostatic bonding and that the electrostatic bonding is sufficiently strong to allow processing of the diamond wafer after bonding to the carrier substrate.

The diamond wafer may be a plain free-standing diamond wafer, a coated diamond wafer (e.g. a metal coated diamond wafer or a diamond wafer with an optical coating such as antireflective coating), or a composite wafer such as a semiconductor-on-diamond wafer (e.g. GaN-on-diamond). In certain embodiments, the diamond material is in the form of polycrystalline diamond material deposited via chemical vapour deposition (i.e. polycrystalline CVD diamond wafers). However, the present invention may also be applied to other forms of diamond material including sintered, high pressure, high temperature (HPHT) synthetic polycrystalline diamond material (PCD) or single crystal diamond materials including CVD synthetic, HPHT synthetic and natural single crystal diamond materials.

The diamond wafer may be bowed prior to electrostatic bonding and the electrostatic bonding pulls the diamond wafer flat.

The carrier substrate is typically a thin (e.g. 100 μm to 2 mm thickness) stand-alone substrate with columbic, Johansen-Rahbek, or any other typical electrostatic bonding design. In one example the bulk of the carrier substrate consisting of a silicon wafer which may be patterned, metalized, and coated with a dielectric according to the specific design of the supplier. Additionally, the stand-alone electrostatic carrier substrate can be designed as a perforated carrier or a different variant to facilitate handling, attachment, mounting, dismounting, etc. Suitable carrier substrates can be obtained from Beam Services, Inc.

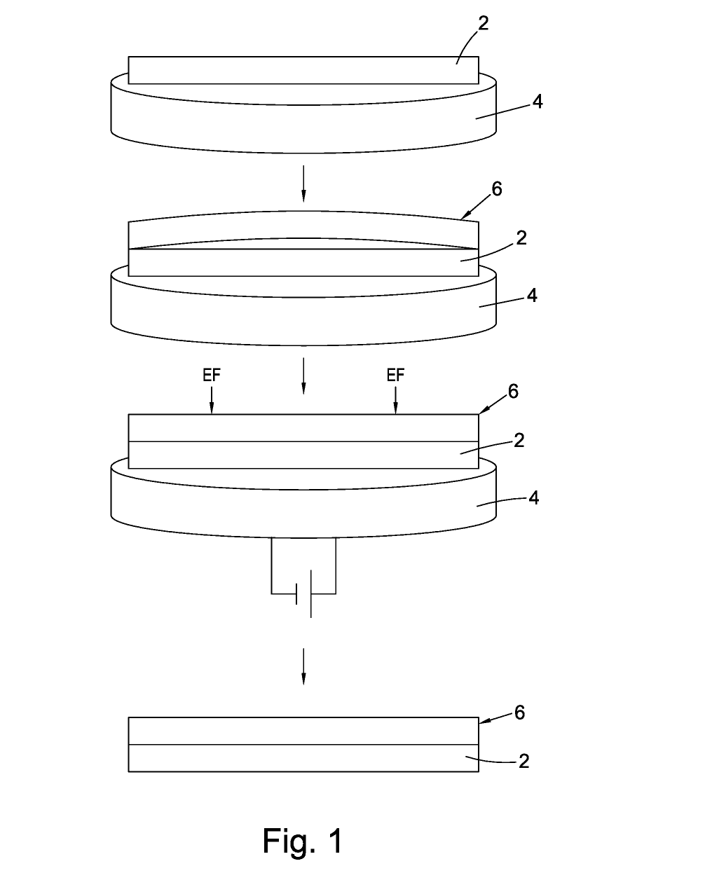

FIG. 1 illustrates the basic method steps. A carrier substrate 2 is first placed on an electrostatic chuck 4. A diamond wafer 6 is then placed on the carrier substrate 2. A voltage is applied to the electrostatic chuck 4 which induces an electrostatic force EF which pulls the diamond wafer 6 flat and bonds the diamond wafer 6 to the carrier substrate 2. This step may be aided by use of a vacuum arrangement to pull the diamond wafer 6 flat prior to, and/or during, the application of the voltage. Finally, the diamond wafer 6 and carrier substrate 2 are removed from the electrostatic chuck 4 with the diamond wafer 6 bonded and held flat to the carrier substrate 2 via residual electrostatic force.

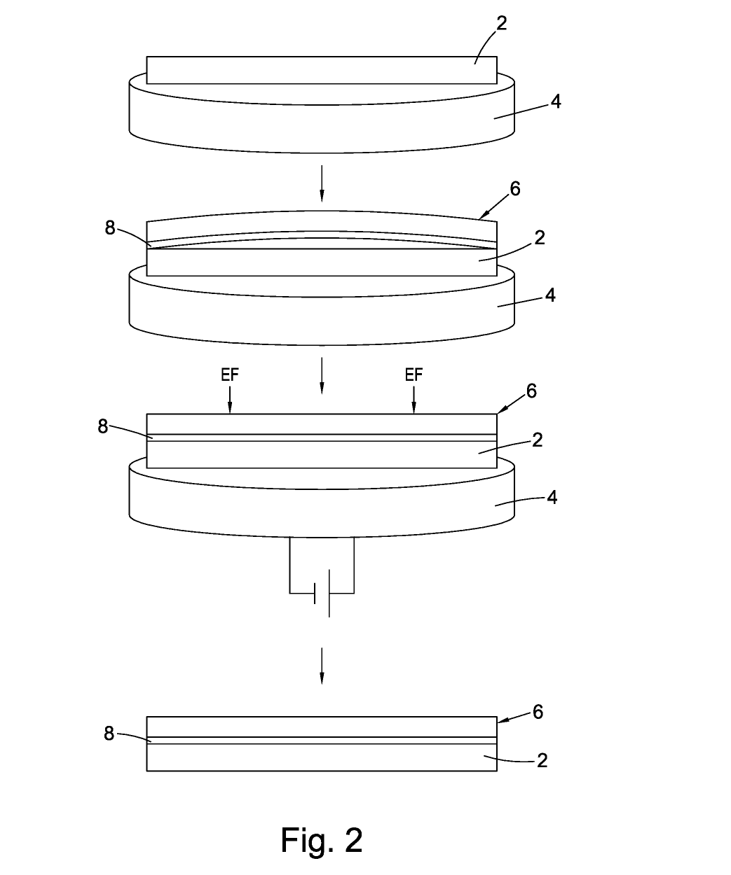

FIG. 2 shows a similar method to that shown in FIG. 1 but in this case an electrically conductive layer 8 (e.g. a layer of conductive material such as a layer of metal or graphite, or a hydrogen terminated diamond surface) is provided on a side of the diamond wafer 6 which is bonded to the carrier substrate 2. As before, a carrier substrate 2 is first placed on an electrostatic chuck 4. The diamond wafer 6 is then placed on the carrier substrate 2 with the electrically conductive layer 8 proximal to the carrier substrate 2. A voltage is applied to the electrostatic chuck 4 which induces an electrostatic force EF which pulls the diamond wafer 6 flat and bonds the diamond wafer 6 to the carrier substrate 2 via the electrically conductive layer 8. Finally, the diamond wafer 6 and carrier substrate 2 are removed from the electrostatic chuck 4 with the diamond wafer 6 bonded and held flat to the carrier substrate 2 via residual electrostatic force. In this configuration, the electrically conductive layer 8 aids electrostatic bonding of the diamond wafer 6 to the carrier substrate 2.

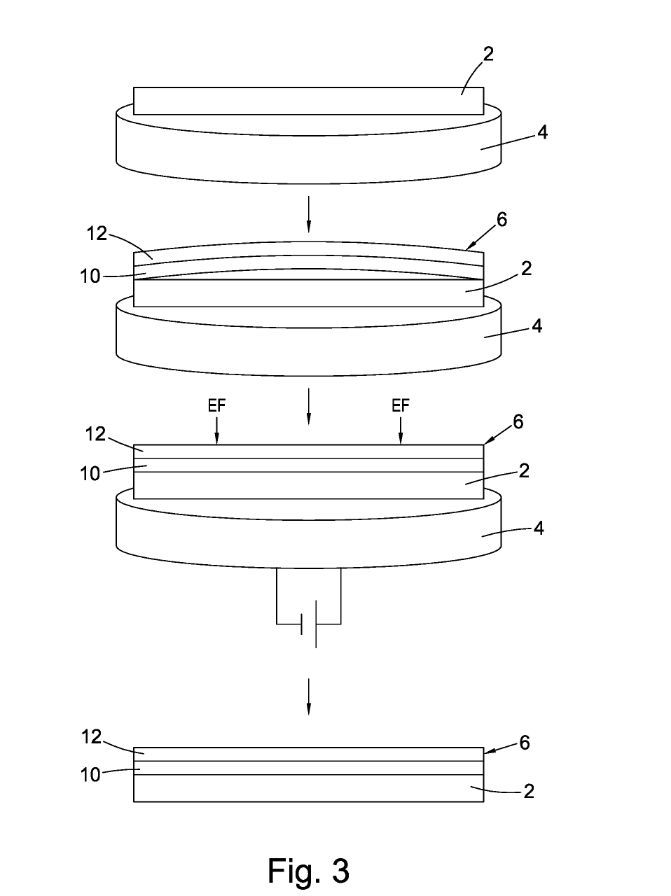

FIG. 3 shows a similar method to that shown in FIGS. 1 and 2 but in this case the diamond wafer 6 is a semiconductor-on-diamond wafer comprising a layer of diamond 10 bonded to a layered semiconductor structure 12, e.g. a GaN epilayer structure. As before, a carrier substrate 2 is first placed on an electrostatic chuck 4. The diamond wafer 6 is then placed on the carrier substrate 2 with the diamond layer 10 proximal to the carrier substrate 2 and the semiconductor layer 12 distal to the carrier substrate 2. A voltage is applied to the electrostatic chuck 4 which induces an electrostatic force which pulls the diamond wafer 6 flat and bonds the diamond wafer 6 to the carrier substrate 2 via the diamond layer 10. Finally, the diamond wafer 6 and carrier substrate 2 are removed from the electrostatic chuck 4 with the diamond wafer 6 bonded and held flat to the carrier substrate 2 via residual electrostatic force. In this configuration, the semiconductor layer structure 12 is exposed for device fabrication. Optionally, an electrically conductive layer can also be provided on the diamond prior to electrostatic bonding to aid electrostatic bonding of the semiconductor-on-diamond wafer 6 to the carrier substrate 2 as described previously with reference to FIG. 2.

While FIGS. 1 to 3 illustrate the application of a voltage to the carrier substrate by placing the carrier substrate on an electrostatic chuck, the voltage can be applied to the carrier substrate via other means such as pins or other electrical connections to the carrier substrate. In this case, the carrier substrate itself can function as a free-standing electrostatic chuck. In all of the aforementioned embodiments, electrostatic bonding is improved by careful preparation of the rear side of the diamond wafer which is to be bonded to the carrier substrate. In this regard, the diamond wafer can be polished on a side of the diamond wafer which is bonded to the carrier substrate prior to electrostatic bonding to have a surface roughness (Rₐ) of no more than 7 μm, 5 μm, 3 μm, 1 μm, 0.5 μm, 0.4 μm, 0.3 μm, 0.2 μm, 0.1 μm, or 0.05 μm. Finer surface finishes can achieve even lower surface roughnesses of no more than 50 nm, 30 nm, 20 nm, 10 nm, or 5 nm. For many applications, it is important that the diamond wafer is processed to a precise thickness with little thickness variation (e.g. less than 25 μm variation, but preferably less than 2 μm/2 cm linear and radial length of travel across the wafer). This is particularly important when a high degree of flatness is required after electrostatic bonding of the diamond wafer to the carrier substrate. For example, when mounting semiconductor-on-diamond wafers on a carrier substrate for subsequent semiconductor device fabrication the mounted wafer must meet strict flatness requirements. As such, the diamond wafer may have a thickness in a range 50 μm to 500 μm, preferably 50 μm to 200 μm. The diamond wafer may also have a thickness variation of no more than 40 μm. Since the diamond wafer may have a diameter of at least 50 mm, 75 mm, 100 mm, or 150 mm, then the wafer should be processed to meet such requirements over relatively large areas.

One complication with the electrostatic bonding process and requirements such as processing of a rear surface of the diamond wafer to meet flatness, roughness, thickness, and thickness variation requirements is that as-grown diamond wafers such as large area polycrystalline CVD diamond wafers, are typically bowed. As such, where the diamond wafer is bowed prior to electrostatic bonding then the electrostatic bonding requires the diamond wafer to be pulled flat to the carrier substrate. If the bow of the initial wafer is too large then this may be difficult to achieve, especially given the rigid nature of the diamond material and especially if the diamond wafer is relatively thick. Accordingly, the state of the initial diamond wafer is important to ensure good electrostatic bonding. For example, the bowing of the diamond wafer prior to electrostatic bonding may in a range 50 μm to 300 μm. Thin diamond wafers may have a significant bow towards the upper end of this range while thicker diamond wafers may require a lower initial bow towards the lower end of this range to achieve good electrostatic bonding. If the diamond wafer is too thick and bowed then electrostatic bonding may not be possible. Ultimately, the flattenability of the wafer is the determining factor. Flattenability is a function of diamond thickness, free-standing bow/warp and grain size. Accordingly, diamond growth conditions play an important role in generating material that is suitable for mounting on a carrier substrate via electrostatic bonding. According to certain examples, a suitable thickness of diamond material is of the order of 50 μm to 150 μm, with a free-standing bow/warp of <1 mm.

In order to dealing with the bowing issue, the electrostatic chuck and/or carrier substrate may also incorporate a vacuum system for pulling the diamond wafer flat. In this regard, one or more holes may be provided in the carrier substrate such that when the diamond wafer is placed on the carrier substrate, a vacuum system can be utilized to pull the diamond wafer flat against the carrier substrate prior to electrostatic bonding.

In addition to the effect of bowing in relation to the requirement to pull the diamond wafer flat as part of the electrostatic bonding process, the bowing also makes surface processing of the rear side of the diamond wafer prior to electrostatic bonding more problematic. The diamond wafer cannot necessarily be surface processed on a rear surface to have a flat configuration prior to bonding as the bow may be too large to process out and/or the requirement to have a uniform thickness may prevent an approach in which the bowed rear surface is surface processed until it is flat. As such, processing of the rear surface to achieve the desired levels of surface roughness and thickness variation must account for the bowing of the diamond wafer. For example, a bowed polishing wheel which is complimentary to the bowed rear surface of the diamond wafer may be utilized or otherwise the bowed diamond wafer may be pushed into a plat configuration for the surface processing. Ideally, in addition to achieving desired values for surface roughness and thickness uniformity, the prepared surface should have a large fraction of the surface area which is flat once electrostatic bonding is applied. For example, one approach for a GaN-on-diamond wafer is to mount the free-standing GaN-on-diamond wafer onto an optical flat via the GaN side of the wafer and directly polish the rough side of diamond. It is possible to successfully mount such a processed GaN-on-diamond wafer to a carrier substrate via electrostatic bonding with as little as 15% total area of diamond polished in this manner. However, there are two important factors governing the success or failure. One is the total thickness variation of the GaN-on-diamond wafer and the other is the average diamond thickness. The thicker the diamond wafer the harder it is to flatten the wafer and electrostatically bond it.

A second approach is to perform pre-silicon handle etch polishing of a diamond-on-GaN-on-silicon wafer using a bowed polishing wheel.

The applied voltage to be applied to achieve electrostatic bonding will depend on a number of factors including the nature of the carrier substrate, the stiffness, the thickness, bow, diameter, and surface finish of the diamond wafer, the strength of the electrostatic bond required for an application, and the requirement to de-bond the diamond wafer from the carrier substrate in certain applications after the desired usage has been completed. Typically, a voltage in a range 500 V to 8000 V may be applied to achieve electrostatic bonding of a diamond wafer to a carrier substrate depending on the aforementioned variables. For certain applications the applied voltage will be at least 1000, 2000, 3000, 4000, 5000, or 6000 V.

Using the methodology as described herein, it is possible to fabricate a mounted diamond wafer comprising: a diamond wafer; and a carrier substrate, wherein the diamond wafer is bonded to the carrier substrate via a residual electrostatic force. Advantageously, for certain applications, such as semiconductor-on-diamond applications, the mounted diamond wafer has the following characteristics: a total thickness variation of no more than 40 μm; a wafer bow of no more than 100 μm; and a wafer warp of no more than 40 μm. Furthermore, for many applications the mounted diamond wafer meets the requirements for total thickness variation, wafer bow, and wafer warp over a diameter of at least 50 mm, 75 mm, 100 mm, or 150 mm.

In relation to the above, it may be noted that an XYZ automated optical comparator can be used to establish the Z-direction height of 300-500 points on a given diamond wafer for various X and Y positions. Consequently, it is possible to build a surface contour map of each diamond wafer before and after mounting and for various electrostatic mounting methodologies.

According to certain examples, the diamond wafer has a thickness of no more than 130 microns and at least 30% of the rear surface of the diamond wafer is polished for electrostatic bonding. A voltage of 6000 V in then applied to electrostatically bond the diamond wafer to a coated silicon carrier substrate and achieve a mounted diamond wafer which is sufficiently flat for lithography applications.

While this invention has been particularly shown and described with reference to embodiments, it will be understood to those skilled in the art that various changes in form and detail may be made without departing from the scope of the invention as defined by the appending claims.

1. A method of bonding a diamond wafer to a carrier substrate, the method comprising:
placing a diamond wafer on a carrier substrate, the diamond wafer having a diameter of at least 50 mm;
applying a voltage to the carrier substrate which induces an electrostatic force which bonds the diamond wafer to the carrier substrate; and
removing the voltage applied to the carrier substrate leaving the diamond wafer bonded to the carrier substrate via residual electrostatic force.

2. A method according to claim 1, wherein the diamond wafer is selected from the group consisting of:
a plain free-standing diamond wafer;
a coated diamond wafer; and
a semiconductor-on-diamond wafer.

3. A method according to claim 1, wherein the diamond wafer is formed of a diamond material selected from the group consisting of:
polycrystalline CVD diamond material;
polycrystalline HPHT diamond material;
single crystal CVD diamond material;
single crystal HPHT diamond material; and
natural single crystal diamond material.

4. A method according to claim 1, wherein an electrically conductive layer is provided on a side of the diamond wafer which is bonded to the carrier substrate.

5. A method according to claim 4, wherein the electrically conductive layer is selected from the group consisting of:
a metal layer;
a graphite layer; or
a hydrogen terminated diamond surface.

6. A method according to claim 1, wherein the diamond wafer is polished on a side of the diamond wafer which is bonded to the carrier substrate prior to electrostatic bonding to have a surface roughness of no more than 0.5 μm, 0.4 μm, 0.3 μm, 0.2 μm, 0.1 μm, or 0.05 μm.

7. A method according to claim 1, wherein the diamond wafer has a thickness in a range 50 μm to 200 μm.

8. A method according to claim 1, wherein the diamond wafer has a diameter of at least 75 mm, 100 mm, or 150 mm.

9. A method according to claim 1, wherein the diamond wafer has a thickness variation of no more than 40 μm.

10. A method according to claim 1, wherein the diamond wafer is bowed prior to electrostatic bonding and the electrostatic bonding pulls the diamond wafer flat, the bowing of the diamond wafer prior to electrostatic bonding being in a range 50 μm to 300 μm.

11. A mounted diamond wafer comprising:
a diamond wafer having a diameter of at least 50 mm;
a carrier substrate;
wherein the diamond wafer is bonded to the carrier substrate via a residual electrostatic force.

12. A mounted diamond wafer according to claim 11, wherein the mounted diamond wafer has the following characteristics:
a total thickness variation of no more than 40 μm;
a wafer bow of no more than 100 μm; and
a wafer warp of no more than 40 μm.

13. A mounted diamond wafer according to claim 12, wherein the mounted diamond wafer meets the requirements for total thickness variation, wafer bow, and wafer warp over a diameter of at least 75 mm, 100 mm, or 150 mm.

14. A mounted diamond wafer according to claim 11, wherein the diamond wafer is selected from the group consisting of:
a plain free-standing diamond wafer;
a coated diamond wafer; and
a semiconductor-on-diamond wafer.

15. A mounted diamond wafer according to claim 11, wherein the diamond wafer is formed of a diamond material selected from the group consisting of:
polycrystalline CVD diamond material;
polycrystalline HPHT diamond material;
single crystal CVD diamond material;
single crystal HPHT diamond material; and
natural single crystal diamond material.

16. A mounted diamond wafer according to claim 11, wherein an electrically conductive layer is provided on a side of the diamond wafer which is bonded to the carrier substrate.

17. A mounted diamond wafer according to claim 16, wherein the electrically conductive layer is selected from the group consisting of:
a metal layer;
a graphite layer; or
a hydrogen terminated diamond surface.
